(19) United States
(12) Patent Application Publication
(10) Pub. No.: US 2023/0063905 A1
(43) Pub. Date: Mar. 2, 2023

(54) SEMICONDUCTOR DEVICE AND METHOD FOR MANUFACTURING THE SAME

(71) Applicant: Taiwan Semiconductor Manufacturing Company, Ltd., Hsinchu (TW)

(72) Inventors: Yung-Hsiang CHEN, Tainan City (TW); Yu-Lung YEH, Kaohsiung City (TW); Yen-Hsiu CHEN, Tainan City (TW); Chihchous CHUANG, Fongshan City (TW); Ching-Hung HUANG, Erlin Township (TW); Wei-Liang CHEN, Tainan City (TW)

(21) Appl. No.: 17/446,573

(22) Filed: Aug. 31, 2021

(51) Int. Cl. H01L 49/02

(52) U.S. Cl. CPC H01L 28/40; H01L 27/14609

(57) ABSTRACT

A metal-insulator-metal (MIM) device may include a first metal layer. The MIM device may include an insulator stack on the first metal layer. The insulator stack may include a first high dielectric constant (high-K) layer on the first metal layer. The insulator stack may include a low dielectric constant (low-K) layer on the first high-K layer. The insulator stack may include a second high-K layer on the low-K layer. The MIM device may include a second metal layer on the insulator stack.

### BACKGROUND

A metal-insulator-metal (MIM) device can be used as a capacitor in a semiconductor device. A MIM device includes two metal layers, with an insulator layer between the two metal layers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2G are diagrams illustrating a sequence of operations for manufacturing a MIM device including an insulator stack, as described herein.

FIG. 3 is a diagram of an example semiconductor device including a group of MIM devices including insulator stacks, as described herein.

FIG. 4 is a diagram of example components of one or more devices of FIG. 1.

FIG. 5 is a flowchart of an example process relating to formation of a MIM device including an insulator stack, as described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A particular application may use a MIM device with a relatively high electrical capacitance. For example, a global shutter in a complementary metal-oxide-semiconductor (CMOS) image sensor may include a MIM device with an electrical capacitance of at least 7 femtoFarads (fF) (e.g., at an operation voltage of 3.3 volts (V)). The insulator layer of a MIM device is a single layer (e.g., a film) comprising a material with low dielectric constant (herein referred to as a low-K material), such as silicon dioxide (SiO₂) or silicon nitride (Si₃N₄). However, while such low-K materials have high band gaps that induce a low leakage current in the MIM device, these low-K materials provide insufficient electrical capacitance (e.g., from approximately 1 if to approximately 2 fF). The insulator layer could alternatively be formed as a single layer comprising a material with a high K (herein referred to as a high-K material), such as tantalum pentoxide (Ta₂O₅), hafnium dioxide (HfO₂), or zirconium dioxide (ZrO₂). However, while such high-K materials may provide sufficient electrical capacitance (e.g., at least 7 fF), these high-K materials have low band gaps that induce a high leakage current in the MIM device.

Some implementations described herein provide techniques and apparatuses for an improved MIM device that provides high electrical capacitance (e.g., at least 7 if) while achieving a low leakage current. The improved MIM device includes a first metal layer (e.g., a capacitor bottom metal (CBM) layer), an insulator stack on the first metal layer, and a second metal layer (e.g., a capacitor top metal (CTM) layer) on the insulator stack. In some implementations, the insulator stack includes at least three layers. For example, the insulator stack may include a first high-K layer, a low-K layer, and a second high-K layer. Here, the first high-K layer is deposited on the first metal layer, the low-K layer is deposited on the first high-K layer, and the second high-K layer is deposited on the low-K layer. The second metal layer is then deposited on the second high-K layer.

The insulator stack of the improved MIM device enables the MIM device to provide a high electrical capacitance (e.g., at least 7 fF at 3.3 V operation) while achieving a low leakage current. More specifically, the high-K layers of the insulator stack have a dielectric constant K that enables a high value capacitor, while the low-K layer of the insulator stack has a high band gap that suppresses the leakage current. Therefore, the improved MIM device may be used in an application that requires a relatively high electrical capacitance. Additional details are provided below.

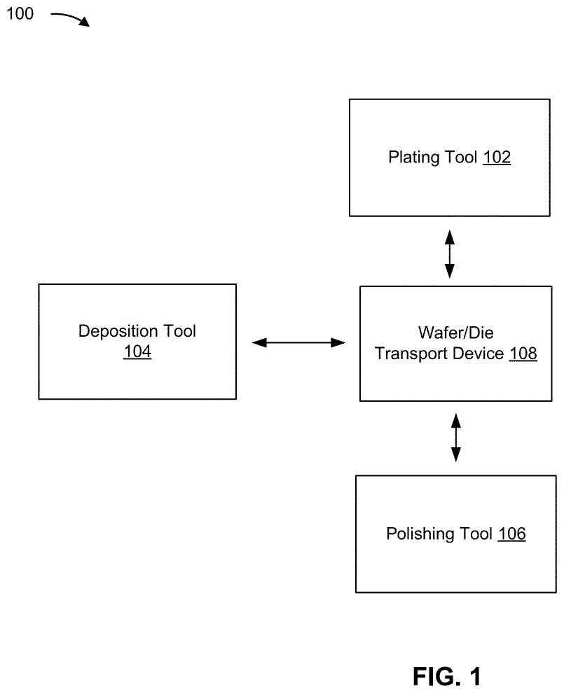

FIG. 1 is a diagram of an example environment 100 in which systems and/or methods described herein may be implemented. As shown in FIG. 1, environment 100 may include a plating tool 102, a deposition tool 104, a polishing tool 106, and a wafer/die transport device 108. The tools and/or devices included in example environment 100 may be included in a semiconductor clean room, a semiconductor foundry, a semiconductor processing and/or manufacturing facility, and/or the like.

Plating tool 102 includes one or more devices capable of plating a substrate (e.g., a semiconductor wafer, a semiconductor device, and/or the like) or a portion thereof with one or more metals. For example, plating tool 102 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or the like. Plating, and particularly electroplating (or electro-chemical deposition), is a process by which conductive structures are formed on a substrate (e.g., a semiconductor wafer, a semiconductor device, and/or the like). Plating may include applying a voltage across an anode formed of a plating material and a cathode (e.g., a substrate). The voltage causes a current to oxidize the anode, which causes the release of plating material ions from the anode. These plating material ions form a plating solution that travels through a plating bath toward the substrate. The plating solution reaches the substrate and deposits plating material ions into trenches, vias, interconnects, and/or other structures in and/or on the substrate. In some implementations, plating tool 102 may perform one or more operations associated with forming a MIM device including an insulator stack, as described herein. For example, in some implementations, plating tool 102 may plate one or more metal layers (e.g., a CBM layer and/or a CTM layer) of the MIM device including the insulator stack described herein.

Deposition tool 104 includes one or more devices capable of depositing various types of materials onto a substrate (e.g., a semiconductor wafer, a semiconductor device, and/or the like). For example, deposition tool 104 may include a chemical vapor deposition tool (e.g., an electrostatic spray tool, an epitaxy tool, and/or another type of chemical vapor deposition tool), a physical vapor deposition tool (e.g., a sputtering tool and/or another type of physical vapor deposition tool), and/or the like. In some implementations, deposition tool 104 may deposit a metal material to form one or more conductors or conductive layers, may deposit an insulating material to form a dielectric or insulating layer, and/or the like as described herein. A sputtering (or sputter deposition) process is a physical vapor deposition (PVD) process that includes one or more techniques to deposit material onto a substrate or a wafer, such as a metal, a dielectric, or another type of material. For example, a sputtering process may include placing the substrate on an anode in a processing chamber, in which a gas (e.g., argon or another chemically inert gas) is supplied and ignited to form a plasma of ions of the gas. The ions in the plasma are accelerated toward a cathode formed of the material to be deposited, which cases the ions to bombard the cathode and release particles of the material. The anode attracts the particles, which causes the particles to travel toward and deposit onto the wafer. In some implementations, deposition tool 104 may perform one or more operations associated with forming a MIM device including an insulator stack, as described herein. For example, in some implementations, deposition tool 104 may deposit one or more metal layers (e.g., the CBM layer and/or the CTM layer) of the MIM device including the insulator stack. As another example, in some implementations, deposition tool 104 may deposit one or more layers of the insulator stack (e.g., one or more high-K layers and/or one or more low-K layers) of the MIM device described herein.

Polishing tool 106 includes one or more devices capable of polishing or planarizing various layers of a wafer or semiconductor device. For example, polishing tool 106 may include a chemical mechanical polishing device and/or another type of polishing device. In some implementations, polishing tool 106 may polish or planarize a layer of deposited or plated material. A layer, a substrate, or a wafer may be planarized using a polishing or planarizing technique such as chemical mechanical polishing/planarization (CMP). A CMP process may include depositing a slurry (or polishing compound) onto a polishing pad. A wafer may be mounted to a carrier, which may rotate the wafer as the wafer is pressed against the polishing pad. The slurry and polishing pad act as an abrasive that polishes or planarizes one or more layers of the wafer as the wafer is rotated. The polishing pad may also be rotated to ensure a continuous supply of slurry is applied to the polishing pad. In some implementations, polishing tool 106 may perform one or more operations associated with forming a MIM device including an insulator stack, as described herein. For example, in some implementations, polishing tool 106 may polish the CBM layer of the MIM device including the insulator stack (e.g., before the insulator stack is formed), one or more layers of the insulator stack (e.g., before a next layer of the insulator stack is formed or before the CTM layer is formed on the insulator stack), and/or the CTM layer of the MIM device including the insulator stack.

Wafer/die transport device 108 includes a mobile robot, a robot arm, a tram or rail car, and/or another type of device that are used to transport wafers and/or dies between semiconductor processing tools 102 through 106 and/or to and from other locations, such as a wafer rack, a storage room, and/or the like. In some implementations, wafer/die transport device 108 may be a programmed device to travel a particular path and/or may operate semi-autonomously or autonomously.

The number and arrangement of devices shown in FIG. 1 are provided as one or more examples. In practice, there may be additional devices, fewer devices, different devices, or differently arranged devices than those shown in FIG. 1. For example, environment 100 may include one or more other semiconductor processing tools that may be used in association with forming a MIM device including an insulator stack. As particular examples, environment 100 may include a coating tool (e.g., a tool associated with forming a photoresist layer), an exposure tool (e.g., a tool associated with exposing one or more portions of the photoresist layer to transfer a pattern to the photoresist layer), a developer tool (e.g., a tool associated with developing the photoresist layer so as to develop the pattern), an etching tool (e.g., a tool associated with removing one or more portions of the substrate according to the pattern to form an opening in which a MIM can be formed), and/or the like. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of environment 100 may perform one or more functions described as being performed by another set of devices of environment 100.

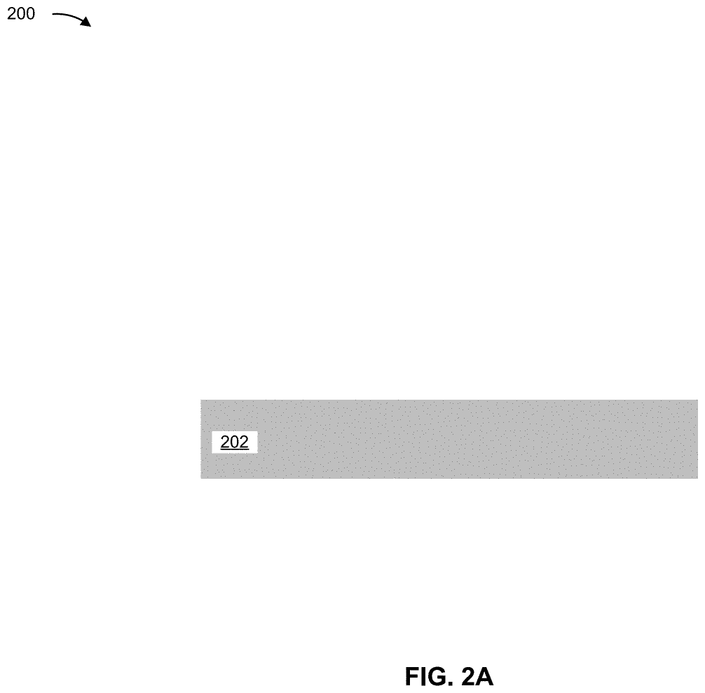

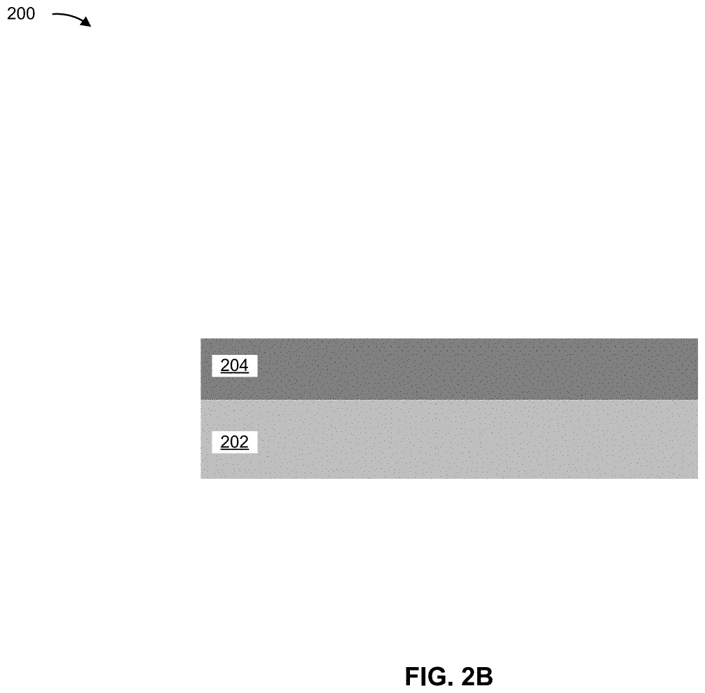

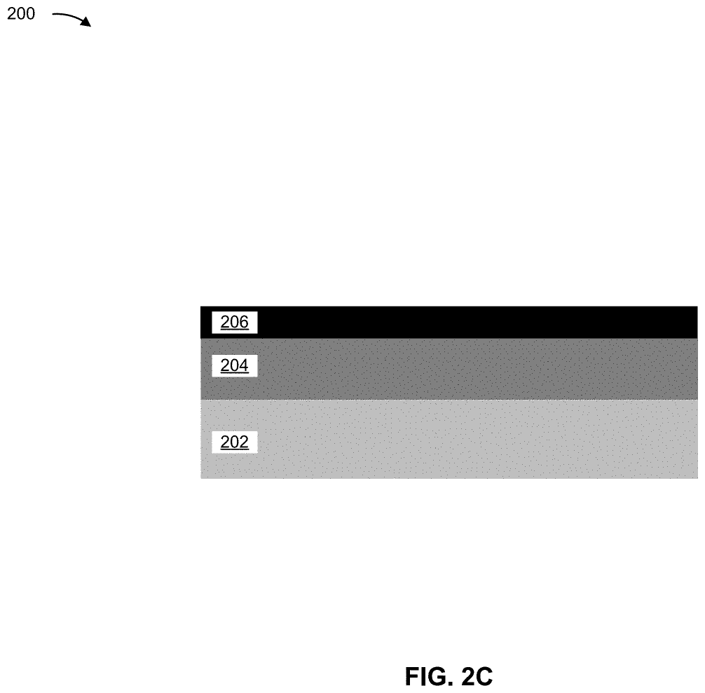

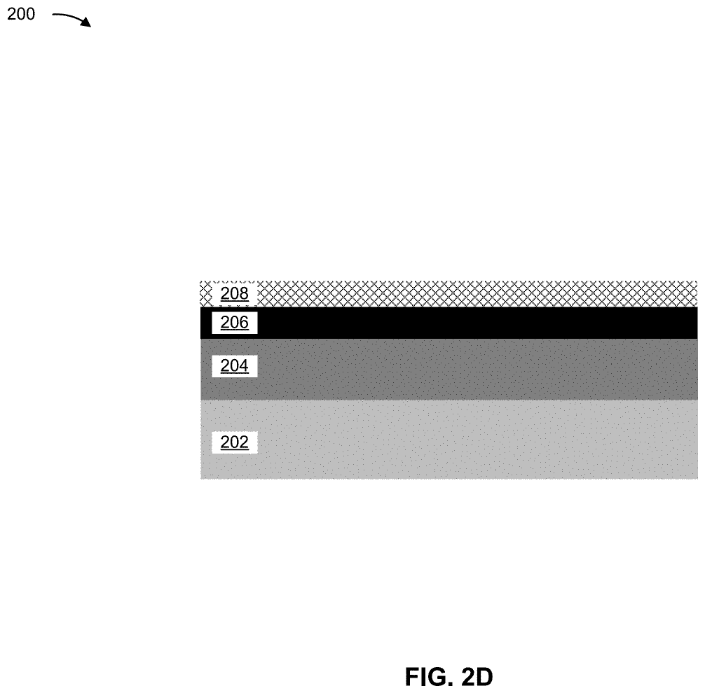

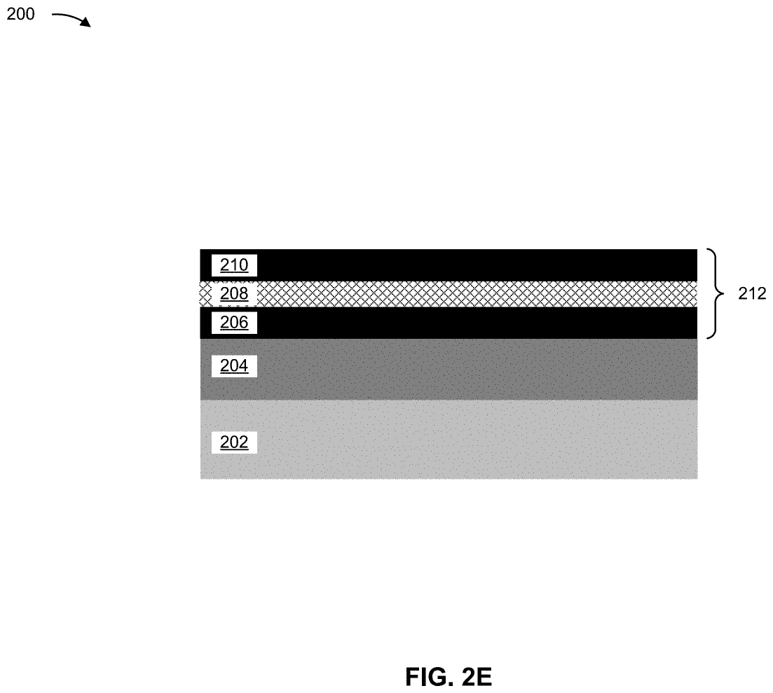

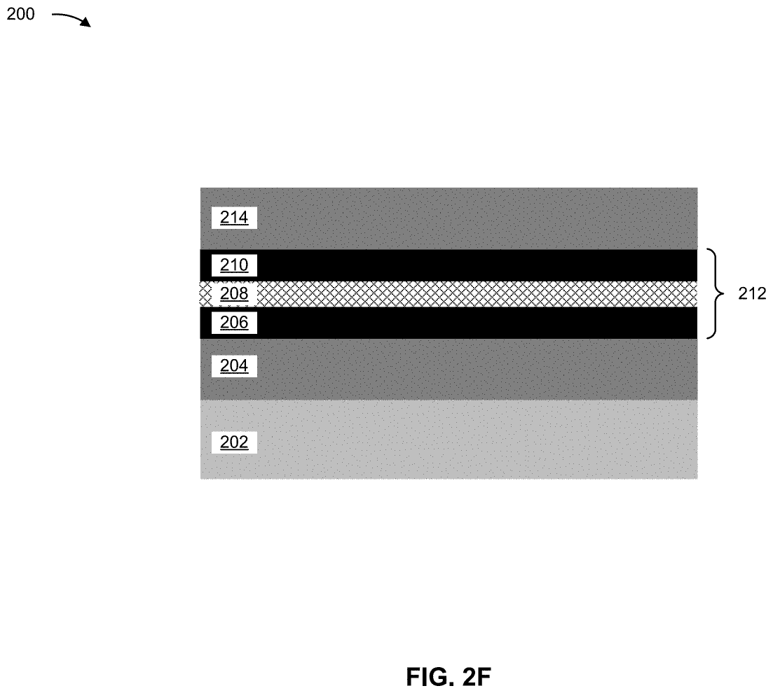

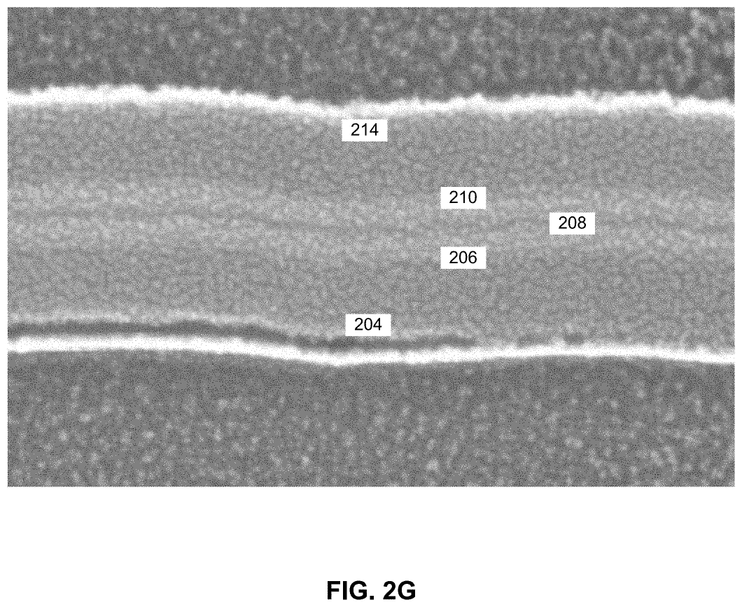

FIGS. 2A-2G are diagrams illustrating a sequence of operations for manufacturing a MIM device including an insulator stack, as described herein.

As shown in FIG. 2A, a MIM device 200 may include a substrate 202. Substrate 202 may include, for example, a semiconductor wafer, a semiconductor device, and/or the like. In some implementations, substrate 202 includes a silicon wafer sliced from a silicon crystal ingot grown as a cylinder. Substrate 202 may have an electrical conductivity value falling between that of a conductor, such as metallic copper, and an insulator, such as glass. In some implementations, substrate 202 may comprise another material, such as germanium, gallium arsenide, silicon germanium, and/or the like.

As shown in FIG. 2B, CBM layer 204 (also referred to herein as a first metal layer 204) may be deposited or otherwise formed on substrate 202. In some implementations, CBM layer 204 includes a metal layer. The metal layer of CBM layer 204 may include, for example, copper, a copper alloy, aluminum, an aluminum alloy, a copper aluminum alloy, tungsten, a tungsten alloy, and/or one or more other metals. In some implementations, CBM layer 204 includes one or more other layers, such as a bottom barrier layer (below the metal layer of CBM layer 204), and/or a top barrier layer (above the metal layer of CBM layer 204). In some implementations, a barrier layer (e.g., the bottom barrier layer and/or the top barrier layer) may act as an anti-oxidation layer (e.g., to protect the metal layer of CBM 204) from being oxidized. In some implementations, the top barrier layer of CBM 204 may act as an adhesion layer (e.g., to improve adhesion between CBM layer 204 and a bottom layer of an insulator stack of MIM device 200). In some implementations, the bottom barrier layer and/or the top barrier layer may comprise titanium, titanium nitride (TiN), tantalum, tantalum nitride (TaN), and/or the like.

In some implementations, one or more tools of environment, described above in connection with FIG. 1, may be utilized to form CBM layer 204. As an example, deposition tool 104 may perform a deposition process (e.g., a chemical vapor deposition process, a physical vapor deposition process, an atomic layer deposition process, and/or the like) to form CBM layer 204 on substrate 202.

As shown in FIG. 2C, a first high-K layer 206 may be deposited or otherwise formed on CBM layer 204. First high-K layer 206 is one insulator layer in an insulator stack 212 of MIM device 200, as described below. In some implementations, first high-K layer 206 comprises a material that has a dielectric constant that is in a range from approximately 20 to approximately 40. For example, first high-K layer 206 may comprise a compound of tantalum and oxygen (e.g., TaₓO_{y}, where x and y are real numbers), such as tantalum pentoxide (Ta₂O₅). As another example, first high-K layer 206 may comprise a compound of hafnium and oxygen (e.g., HfₓO_{y}, where x and y are real numbers), such as hafnium dioxide (HfO₂). As another example, first high-K layer 206 may comprise a compound of zirconium and oxygen (e.g., ZrₓO_{y}, where x and y are real numbers), such as zirconium dioxide (ZrO₂). In some implementations, a thickness of first high-K layer 206 may depend on a dielectric constant of the material from which first high-K layer 206 is formed. For example, in some implementations, when first high-K layer 206 is formed from Ta₂O₅, a thickness of first high-K layer 206 may be in a range from approximately 120 angstrom (Å) to approximately 150 Å.

In some implementations, one or more tools of environment, described above in connection with FIG. 1, may be utilized to form first high-K layer 206. As an example, deposition tool 104 may perform a deposition process (e.g., a chemical vapor deposition process, a physical vapor deposition process, an atomic layer deposition process, and/or the like) to form first high-K layer 206 on CBM layer 204.

As shown in FIG. 2D, a low-K layer 208 may be deposited or otherwise formed on the first high-K layer 206. Low-K layer 208 is one insulator layer in an insulator stack 212 of MIM device 200, as described below. In some implementations, low-K layer 208 comprises a material that has a dielectric constant that is less than or equal to approximately 10. For example, low-K layer 208 may comprise a compound of aluminum and oxygen (e.g., AlₓO_{y}, where x and y are real numbers), such as aluminum oxide (Al₂O₃). As another example, low-K layer 208 may comprise a compound of silicon and oxygen (e.g., SiₓO_{y}, where x and y are real numbers), such as silicon dioxide (SiO₂). As another example, low-K layer 208 may comprise a compound of silicon and nitrogen (e.g., SiₓN_{y}, where x and y are real numbers), such as silicon nitride (Si₃N₄). In some implementations, low-K layer 208 has a band gap that is greater than or equal to approximately 5 electron-volts (eV). In some implementations, a thickness of low-K layer 208 may depend on a dielectric constant of the material from which low-K layer 208 is formed. For example, in some implementations, when low-K layer 208 is formed from Al₂O₃, a thickness of low-K layer 208 may be in a range from approximately 20 Å to approximately 40 Å. In some implementations, a thickness of low-K layer 208 is in a range from approximately 20% to approximately 60% of a thickness of first high-K layer 206 and/or second high-K layer 210. In some implementations, the thickness of low-K layer 208 being in the range from approximately 20% to approximately 60% of the thickness of first high-K layer 206 and/or second high-K layer 210 enables MIM device 200 to achieve a high breakdown voltage while suppressing leakage current, as described herein.

In some implementations, one or more tools of environment, described above in connection with FIG. 1, may be utilized to form low-K layer 208. As an example, deposition tool 104 may perform a deposition process (e.g., a chemical vapor deposition process, a physical vapor deposition process, an atomic layer deposition process, and/or the like) to form low-K layer 208 on first high-K layer 206.

As shown in FIG. 2E, a second high-K layer 210 may be deposited or otherwise formed on low-K layer 208. Second high-K layer 210 is one insulator layer in insulator stack 212 of MIM device 200, as described below. In some implementations, second high-K layer 210 comprises a material that has a dielectric constant that is in a range from approximately 20 to approximately 40. For example, second high-K layer 210 may comprise a compound of tantalum and oxygen (e.g., TaₓO_{y}, where x and y are real numbers), such as Ta₂O₅. As another example, second high-K layer 210 may comprise a compound of hafnium and oxygen (e.g., HfₓO_{y}, where x and y are real numbers), such as HfO₂. As another example, second high-K layer 210 may comprise a compound of zirconium and oxygen (e.g., ZrₓO_{y}, where x and y are real numbers), such as ZrO₂. In some implementations, a thickness of second high-K layer 210 may depend on a dielectric constant of the material from which second high-K layer 210 is formed. For example, in some implementations, when second high-K layer 210 is formed from Ta₂O₅, a thickness of second high-K layer 210 may be in a range from approximately 120 Å to approximately 150 Å.

In some implementations, second high-K layer 210 may be formed from a same material as first high-K layer 206. That is, in some implementations, first high-K layer 206 and second high-K layer 210 are formed from a same type of material. Alternatively, first high-K layer 206 and second high-K layer 210 may be formed from different types of material. Second high-K layer 210 may be formed such that second high-K layer 210 has a same thickness as first high-K layer 206. That is, in some implementations, a thickness of first high-K layer 206 matches a thickness of second high-K layer 210. Alternatively, first high-K layer 206 and second high-K layer 210 may have different thicknesses.

In some implementations, one or more tools of environment, described above in connection with FIG. 1, may be utilized to form second high-K layer 210. As an example, deposition tool 104 may perform a deposition process (e.g., a chemical vapor deposition process, a physical vapor deposition process, an atomic layer deposition process, and/or the like) to form second high-K layer 210 on low-K layer 208.

As indicated in FIG. 2E, first high-K layer 206, low-K layer 208, and second high-K layer 210 form insulator stack 212 of MIM device 200. In some implementations, a total thickness of insulator stack 212 may depend on dielectric constants of first high-K layer 206, low-K layer 208, and second high-K layer 210. For example, when first high-K layer 206 and second high-K layer 210 are formed from Ta₂O₅ and second high-K layer 210 is formed from Al₂O₃, a total thickness of insulator stack 212 may be in a range from approximately 280 Å to approximately 320 Å (e.g., when MIM device 200 is a 7 fF capacitor).

Notably, while insulator stack 212 of MIM device 200 is illustrated as including two high-K layers and one low-K layer, other implementations are possible. For example, in another implementation, an insulator stack of MIM device may include three high-K layers and two low-K layers, where the high-K layers and the low-K layers alternate within the insulator stack. In general, an insulator stack may include at least two high-K layers and one or more low-K layers, where the at least two high-K layers and the one or more low-K layers alternate within the insulator stack.

As shown in FIG. 2F, CTM layer 214 (also referred to herein as a second metal layer 214) may be deposited or otherwise formed on insulator stack 212 (i.e., on second high-K layer 210). In some implementations, CTM layer 214 includes a metal layer. The metal layer of CTM layer 214 may include, for example, copper, a copper alloy, aluminum, an aluminum alloy, a copper aluminum alloy, tungsten, a tungsten alloy, and/or one or more other metals. In some implementations, CTM layer 214 includes one or more other layers, such as a bottom barrier layer (below the metal layer of CTM layer 214), and/or a top barrier layer (above the metal layer of CTM layer 214). In some implementations, a barrier layer (e.g., the bottom barrier layer and/or the top barrier layer) may act as an anti-oxidation layer (e.g., to protect the metal layer of CTM 214) from being oxidized. In some implementations, the bottom barrier layer of CTM layer 214 may act as an adhesion layer (e.g., to improve adhesion between CTM layer 214 and a top layer of insulator stack 212 of MIM device 200). In some implementations, the bottom barrier layer and/or the top barrier layer may comprise titanium, TiN, tantalum, TaN, and/or the like.

In some implementations, CTM layer 214 may be formed from a same material as CBM layer 204. In some implementations, CTM layer 214 and CBM layer 204 are formed from different types of material. In some implementations, CTM layer 214 may be formed such that CTM layer 214 has a same thickness as CBM layer 204. In some implementations, a thickness of CTM layer 214 is different from a thickness of CBM layer 204.

In some implementations, one or more tools of environment, described above in connection with FIG. 1, may be utilized to form CTM layer 214. As an example, deposition tool 104 may perform a deposition process (e.g., a chemical vapor deposition process, a physical vapor deposition process, an atomic layer deposition process, and/or the like) to form CTM layer 214 on insulator stack 212.

Notably, in some implementations, one or more of layers of MIM device may have a slight curvature in practice. That is, when manufactured, one or more layers of MIM device 200 may not be planar. FIG. 2G is a portion of an image of a cross-section of an actual MIM device 200. As can be seen in FIG. 2G, a surface of one or more layers of MIM device 200 may in some areas have a slight curvature (i.e., not be perfectly planar).

In operation, insulator stack 212 of MIM device 200 enables MIM device 200 to provide a high electrical capacitance (e.g., at least 7 fF at 3.3 V operation) while achieving a low leakage current (e.g., a leakage current of no more than 1.0×10⁻¹⁰ ampere (A) at 3.3 V operation with a 7 fF capacitor).

As one example, first high-K layer 206 and second high-K layer 210 may comprise Ta₂O₅, and low-K layer 208 may comprise Al₂O₃ (e.g., such that insulator stack 212 includes a Ta₂O₅/Al₂O₃/Ta₂O₅ stack). Here, the Ta₂O₅ first high-K layer 206 and the Ta₂O₅ second high-K layer 210 provide a sufficient dielectric constant to provide a high value capacitor (e.g., greater than or equal to approximately 7 fF), while the Al₂O₃ low-K layer 208 provides a sufficiently high band gap to suppress leakage current (e.g., less than or equal to approximately 1.0×10⁻¹⁰ ampere (A)). In this example, a large difference between the band gaps of Ta₂O₅ and Al₂O₃ mean that electron tunneling is difficult, thereby suppressing the leakage current.

Notably, MIM device 200 achieves a high breakdown voltage while suppressing leakage current. For example, when the insulator stack 212 includes a Ta₂O₅/Al₂O₃/Ta₂O₅ stack as described above, MIM device 200 may achieve a breakdown voltage of at least approximately 14.8 V, meaning that MIM device 200 can operate at a relatively high voltage while suppressing the leakage current. For comparison, a related MIM device may achieve a breakdown voltage of 14.8 V if designed to provide at least 7 fF capacitance using a single high-K film. However, leakage current performance of such a related MIM device is significantly lower (e.g., on the order of three to four times lower) than that of MIM device 200.

Furthermore, MIM device 200 may achieve a desirable voltage coefficient of capacitance (VCC). For example, when the insulator stack 212 includes a Ta₂O₅/Al₂O₃/Ta₂O₅ stack as described above, MIM device 200 achieves a VCC of less than approximately 2% in a ±5 V range of operation voltage.

Additionally, MIM device 200 may achieve a desirable temperature coefficient of capacitance (TCC). For example, when the insulator stack 212 includes a Ta₂O₅/Al₂O₃/Ta₂O₅ stack as described above, MIM device 200 achieves a TCC of less than approximately 1.5% in a temperature range from approximately 0 degrees Celsius (° C.) to approximately 125° C.

Further, MIM device 200 may achieve a desirable time-dependent dielectric breakdown (TDDB). For example, when the insulator stack 212 includes a Ta₂O₅/Al₂O₃/Ta₂O₅ stack as described above, MIM device 200 may pass 125° C. TDDB test at a 3.3 V operation voltage.

As indicated above, FIGS. 2A-2G are provided as examples. Other examples may differ from what is described with regard to FIGS. 2A-2G.

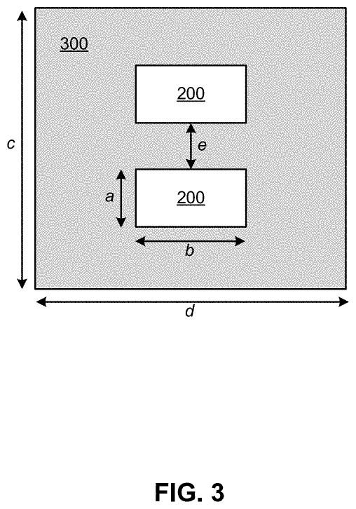

FIG. 3 is a diagram of an example semiconductor device 300 including a group of MIM devices 200 including insulator stacks 212. FIG. 3 shows a plan view of semiconductor device 300 (e.g., such that a top surface of MIM device 200 is shown in FIG. 3). In some implementations, semiconductor device 300 is, for example, a pixel in an image sensor (e.g., a CMOS image sensor).

In some implementations, semiconductor device 300 may include one or more MIM devices 200. For example, as shown in FIG. 3, semiconductor device 300 may, in some implementations, include two MIM devices 200 per pixel. Notably, there is included a single related MIM device in a pixel. The inclusion of at least two MIM devices 200 in a pixel allows for one MIM device 200 to save an image signal and another MIM device 200 to save a background signal, thereby allowing a noise ratio to be decreased (e.g., by subtracting the background signal from the image signal).

In some implementations, an area of a given MIM device 200 (e.g., an area defined by dimensions a and b of MIM device 200, as shown in FIG. 3) is less than or equal to approximately 2 square micrometers (μm²). Here, the increased capacitance achieved by MIM device 200 allows the area to be reduced (e.g., as compared to a related MIM device). For example, if an effective capacitance of 32 fF is needed, an area of a related MIM device (e.g., that provides capacitance of only 2 if) needs to be 16 μm². However, MIM device 200 can provide at least 7 fF of capacitance, meaning that the area of MIM device 200 can be decreased (e.g., by approximately 28%), thereby increasing an area of light collection of the pixel.

In some implementations, a total area MIM devices 200 of semiconductor device 300 is less than or equal to approximately 20% of an area of semiconductor device 300 (e.g., an area defined by dimensions c and d of semiconductor device 300, as shown in FIG. 3). Notably, a related MIM device may consume 40% or more of the pixel area.

In some implementations, a distance e between MIM devices 200 of semiconductor device 300 is greater than or equal to approximately 1.2 μm. In some implementations, such a distance may be maintained to avoid under etching during an etch process associated with forming MIM device 200.

As indicated above, FIG. 3 is provided as an example. Other examples may differ from what is described with regard to FIG. 3.

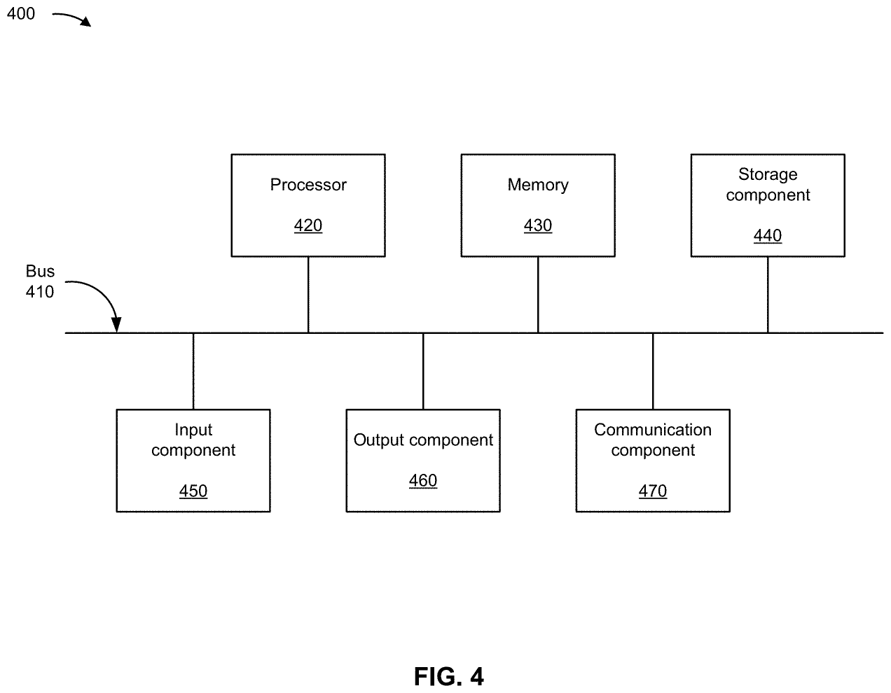

FIG. 4 is a diagram of example components of a device 400, which may correspond to plating tool 102, deposition tool 104, polishing tool 106, and/or wafer/die transport device 108. In some implementations, plating tool 102, deposition tool 104, polishing tool 106, and/or wafer/die transport device 108 may include one or more devices 400 and/or one or more components of device 400. As shown in FIG. 4, device 400 may include a bus 410, a processor 420, a memory 430, a storage component 440, an input component 450, an output component 460, and a communication component 470.

Bus 410 includes a component that enables wired and/or wireless communication among the components of device 400. Processor 420 includes a central processing unit, a graphics processing unit, a microprocessor, a controller, a microcontroller, a digital signal processor, a field-programmable gate array, an application-specific integrated circuit, and/or another type of processing component. Processor 420 is implemented in hardware, firmware, or a combination of hardware and software. In some implementations, processor 420 includes one or more processors capable of being programmed to perform a function. Memory 430 includes a random access memory, a read only memory, and/or another type of memory (e.g., a flash memory, a magnetic memory, and/or an optical memory).

Storage component 440 stores information and/or software related to the operation of device 400. For example, storage component 440 may include a hard disk drive, a magnetic disk drive, an optical disk drive, a solid state disk drive, a compact disc, a digital versatile disc, and/or another type of non-transitory computer-readable medium. Input component 450 enables device 400 to receive input, such as user input and/or sensed inputs. For example, input component 450 may include a touch screen, a keyboard, a keypad, a mouse, a button, a microphone, a switch, a sensor, a global positioning system component, an accelerometer, a gyroscope, an actuator, and/or the like. Output component 460 enables device 400 to provide output, such as via a display, a speaker, and/or one or more light-emitting diodes. Communication component 470 enables device 400 to communicate with other devices, such as via a wired connection and/or a wireless connection. For example, communication component 470 may include a receiver, a transmitter, a transceiver, a modem, a network interface card, an antenna, and/or the like.

Device 400 may perform one or more processes described herein. For example, a non-transitory computer-readable medium (e.g., memory 430 and/or storage component 440) may store a set of instructions (e.g., one or more instructions, code, software code, program code, and/or the like) for execution by processor 420. Processor 420 may execute the set of instructions to perform one or more processes described herein. In some implementations, execution of the set of instructions, by one or more processors 420, causes the one or more processors 420 and/or the device 400 to perform one or more processes described herein. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 4 are provided as an example. Device 400 may include additional components, fewer components, different components, or differently arranged components than those shown in FIG. 4. Additionally, or alternatively, a set of components (e.g., one or more components) of device 400 may perform one or more functions described as being performed by another set of components of device 400.

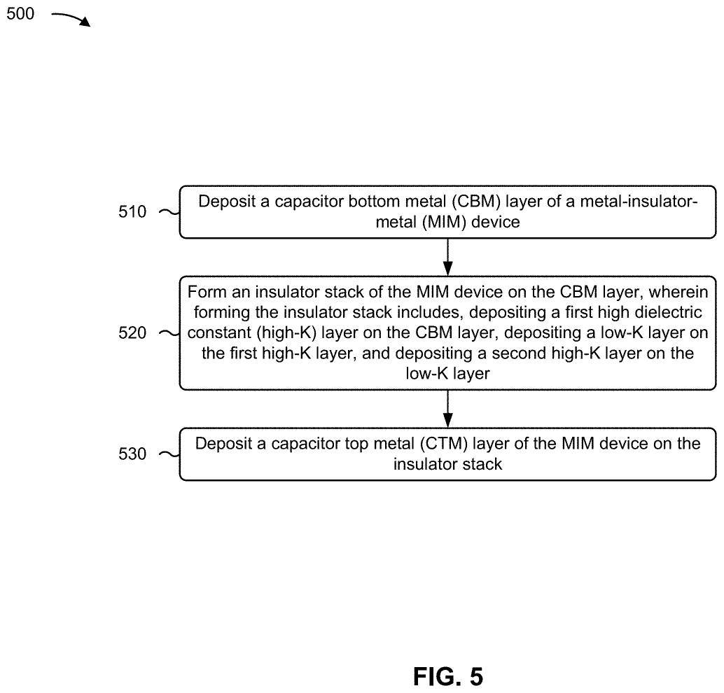

FIG. 5 is a flowchart of an example process 500 relating to formation of a MIM device 200 including an insulator stack 212, as described herein. In some implementations, one or more process blocks of FIG. 5 may be performed by a device (e.g., one or more of the semiconductor processing tools depicted in FIG. 1). In some implementations, one or more process blocks of FIG. 5 may be performed by another device or a group of devices separate from or including the one or more tools depicted in FIG. 1.

As shown in FIG. 5, process 500 may include depositing a CBM layer of a MIM device (block 510). For example, the device (e.g., using processor 420, memory 430, storage component 440, input component 450, output component 460, communication component 470, and/or the like) may deposit a CBM layer 204 of a MIM device 200 on a substrate 202, as described above.

As further shown in FIG. 5, process 500 may include forming an insulator stack of the MIM device on the CBM layer, wherein forming the insulator stack includes depositing a first high-K layer on the CBM layer, depositing a low-K layer on the first high-K layer, and depositing a second high-K layer on the low-K layer (block 520). For example, the device (e.g., using processor 420, memory 430, storage component 440, input component 450, output component 460, communication component 470, and/or the like) may form an insulator stack 212 of the MIM device 200 on the CBM layer 204, wherein forming the insulator stack 212 includes depositing a first high-K layer 206 on the CBM layer 204, depositing a low-K layer 208 on the first high-K layer 206, and depositing a second high-K layer 210 on the low-K layer 208, as described above.

As further shown in FIG. 5, process 500 may include depositing a CTM layer of the MIM device on the insulator stack (block 530). For example, the device (e.g., using processor 420, memory 430, storage component 440, input component 450, output component 460, communication component 470, and/or the like) may deposit a CTM layer 214 of the MIM device 200 on the insulator stack 212, as described above.

Process 500 may include additional implementations, such as any single implementation or any combination of implementations described below and/or in connection with one or more other processes described elsewhere herein.

In a first implementation, the first high-K layer 206 and the second high-K layer 210 have a dielectric constant that is in a range from approximately 20 to approximately 40.

In a second implementation, alone or in combination with the first implementation, the first high-K layer 206 and the second high-K layer 210 are formed from a same type of material.

In a third implementation, alone or in combination with one or more of the first and second implementations, a thickness of the first high-K layer 206 matches a thickness of the second high-K layer 210.

In a fourth implementation, alone or in combination with one or more of the first through third implementations, the first high-K layer 206 and the second high-K layer 210 comprise Ta₂O₅, HfO₂, or ZrO₂.

In a fifth implementation, alone or in combination with one or more of the first through fourth implementations, the low-K layer 208 has a dielectric constant that is less than or equal to approximately 10.

In a sixth implementation, alone or in combination with one or more of the first through fifth implementations, the low-K layer 208 has a band gap that is greater than or equal to approximately 5 eV.

In a seventh implementation, alone or in combination with one or more of the first through sixth implementations, a thickness of the low-K layer 208 is in a range from approximately 20% to approximately 60% of a thickness of the first high-K layer 206 or the second high-K layer 210.

In an eighth implementation, alone or in combination with one or more of the first through seventh implementations, the low-K layer 208 comprises Al₂O₃, SiO₂, or Si₃N₄.

In a ninth implementation, alone or in combination with one or more of the first through eighth implementations, an area of the MIM device 200 is less than or equal to approximately 2 μm².

In a tenth implementation, alone or in combination with one or more of the first through ninth implementations, the MIM device 200 is a first MIM device 200 and a semiconductor device 300 further comprises a second MIM device 200.

In an eleventh implementation, alone or in combination with one or more of the first through tenth implementations, a total area of the first MIM device 200 and the second MIM device 200 is less than or equal to approximately 20% of an area of the semiconductor device 300.

In a twelfth implementation, alone or in combination with one or more of the first through eleventh implementations, a distance between the first MIM device 200 and the second MIM device 200 is greater than or equal to approximately 1.2 μm.

In a thirteenth implementation, alone or in combination with one or more of the first through twelfth implementations, the semiconductor device 300 is a pixel in an image sensor.

Although FIG. 5 shows example blocks of process 500, in some implementations, process 500 may include additional blocks, fewer blocks, different blocks, or differently arranged blocks than those depicted in FIG. 5. Additionally, or alternatively, two or more of the blocks of process 500 may be performed in parallel.

In this way, a MIM device including an insulator stack (e.g., rather than a single insulator layer) may be designed to provide a high electrical capacitance (e.g., at least 7 fF at 3.3 V operation) while achieving a low leakage current. More specifically, the high-K layers of the insulator stack have a dielectric constant K that enables a high value capacitor, while the low-K layer of the insulator stack has a high band gap that suppresses the leakage current. Therefore, the MIM device including the insulator stack may be used in an application that requires a relatively high electrical capacitance. Further, the MIM device including the insulator stack achieves a high breakdown voltage (e.g., approximately 14.8 V), a low VCC (e.g., less than approximately 2% in a ±5 V range of operation voltage), a low TCC (e.g., less than approximately 1.5% in a temperature range from approximately 0° C. to approximately 125° C.), and an acceptable TDDB (e.g., by passing can pass a 125° C. TDDB test at 3.3 V operation voltage), as described above.

As described in greater detail above, some implementations described herein provide a MIM device, a semiconductor device including a MIM device, and a method of manufacturing a MIM device.

In some implementations, a MIM device includes a first metal layer, an insulator stack on the first metal layer, and a second metal layer. In some implementations, the insulator stack includes a first high-K layer on the first metal layer, a low-K layer on the first high-K layer, and a second high-K layer on the low-K layer.

In some implementations, a semiconductor device includes a MIM device including a CBM layer. In some implementations, the semiconductor device includes an insulator stack on the CBM layer. Here, the insulator stack may include at least two high-K layers and one or more low-K layers, where the at least two high-K layers and the one or more low-K layers alternate within the insulator stack. In some implementations, the semiconductor device includes a CTM layer on the insulator stack.

In some implementations, a method includes depositing a CBM layer of a MIM device. In some implementations, the method includes forming an insulator stack of the MIM device on the CBM layer. Here, forming the insulator stack may include depositing a first high-K layer on the CBM layer, depositing a low-K layer on the first high-K layer, and depositing a second high-K layer on the low-K layer. In some implementations, the method includes depositing a CTM layer of the MIM device on the insulator stack.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A metal-insulator-metal (MIM) device, comprising:
a first metal layer;
an insulator stack on the first metal layer, the insulator stack including:
a first high dielectric constant (high-K) layer on the first metal layer,
a low dielectric constant (low-K) layer on the first high-K layer, and
a second high-K layer on the low-K layer; and
a second metal layer on the insulator stack.

2. The MIM device of claim 1, wherein the first high-K layer and the second high-K layer
have a dielectric constant that is in a range from approximately 20 to approximately 40.

3. The MIM device of claim 1, wherein the first high-K layer and the second high-K layer are formed from a same type of material.

4. The MIM device of claim 1, wherein a thickness of the first high-K layer matches a thickness of the second high-K layer.

5. The MIM device of claim 1, wherein the first high-K layer and the second high-K layer comprise tantalum pentoxide (Ta₂O₅), hafnium dioxide (HfO₂), or zirconium dioxide (ZrO₂).

6. The MIM device of claim 1, wherein the low-K layer has a dielectric constant that is less than or equal to approximately 10.

7. The MIM device of claim 1, wherein the low-K layer has a band gap that is greater than or equal to approximately 5 electron-volts (eV).

8. The MIM device of claim 1, wherein a thickness of the low-K layer is in a range from approximately 20% to approximately 60% of a thickness of the first high-K layer or the second high-K layer.

9. The MIM device of claim 1, wherein the low-K layer comprises aluminum oxide (Al₂O₃), silicon dioxide (SiO₂), or silicon nitride (Si₃N₄).

10. The MIM device of claim 1, wherein an area of the MIM device is less than or equal to approximately 2 square micrometers.

11. A semiconductor device, comprising:
a metal-insulator-metal (MIM) device including:
a capacitor bottom metal (CBM) layer;
an insulator stack on the CBM layer, the insulator stack including at least two high dielectric constant (high-K) layers and one or more low dielectric constant (low-K) layers,
wherein the at least two high-K layers and the one or more low-K layers alternate within the insulator stack; and
a capacitor top metal (CTM) layer on the insulator stack.

12. The semiconductor device of claim 11, wherein the at least two high-K layers are formed from a same type of material and have a same thickness.

13. The semiconductor device of claim 11, wherein a thickness of a low-K layer of the one or more low-K layers is in a range from approximately 20% to approximately 60% of a thickness of a high-K layer of the at least two high-K layers.

14. The semiconductor device of claim 11, wherein an area of the MIM device is less than or equal to approximately 2 square micrometers.

15. The semiconductor device of claim 11, wherein the MIM device is a first MIM device and the semiconductor device further comprises a second MIM device.

16. The semiconductor device of claim 15, wherein a total area of the first MIM device and the second MIM device is less than or equal to approximately 20% of an area of the semiconductor device.

17. The semiconductor device of claim 15, wherein a distance between the first MIM device and the second MIM device is greater than or equal to approximately 1.2 micrometers.

18. The semiconductor device of claim 11, wherein the semiconductor device is a pixel in an image sensor.

19. A method, comprising:
depositing a capacitor bottom metal (CBM) layer of a metal-insulator-metal (MIM) device;
forming an insulator stack of the MIM device on the CBM layer, wherein forming the insulator stack includes:
depositing a first high dielectric constant (high-K) layer on the CBM layer,
depositing a low dielectric constant (low-K) layer on the first high-K layer, and
depositing a second high-K layer on the low-K layer; and
depositing a capacitor top metal (CTM) layer of the MIM device on the insulator stack.

20. The method of claim 19, wherein the first high-K layer and the second high-K layer comprise tantalum pentoxide (Ta₂O₅) and the low-K layer comprises aluminum oxide (Al₂O₃).
